(19) United States
(12) Patent Application Publication
(10) Pub. No.: US 2018/0118890 A1
(43) Pub. Date: May 3, 2018

(54) ORGANOSILICONE COMPOSITION, REFLECTIVE COATING, PREPARATION METHOD THEREFOR AND PHOTOVOLTAIC MODULE COMPRISING SAME

(71) Applicant: BYD COMPANY LIMITED, SHENZHEN (CN)

(72) Inventors: FULAN TANG, SHENZHEN (CN); WEI ZHOU, SHENZHEN (CN); XIANKUAN LI, SHENZHEN (CN)

(21) Appl. No.: 15/855,900

(22) Filed: Dec. 27, 2017

Related U.S. Application Data
(63) Continuation of application No. PCT/CN2016/077690, filed on Mar. 29, 2016.

(30) Foreign Application Priority Data
Jun. 30, 2015 (CN) 201510373311.7

(51) Int. Cl. C08G 77/42; C09D 5/33; C08G 59/14; C09D 183/10; C09D 163/00; H01L 31/054; H01L 31/049

(52) U.S. Cl. CPC C08G 77/42; C09D 5/004; C08G 59/1494; C09D 183/10; C08K 2003/2241; H01L 31/0547; H01L 31/049; C08K 2201/005; C09D 163/00

(57) ABSTRACT

A silicone composition, a reflective coating and a preparation method therefor, and a photovoltaic assembly comprising the reflective coating are disclosed. The silicone composition comprises a base polymer component, a catalyst, a cross-linking agent and reflective particles, wherein the base polymer component, the catalyst and the cross-linking agent are not mixed simultaneously before use; the base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, 10-20 parts by weight of a siloxane resin having at least two Si-Vi bonds; and the cross-linking agent is a polyorganosiloxane having at least two Si—H bonds.

### CROSS-REFERENCE TO RELATED APPLICATION

This application is a continuation application of International Application No. PCT/CN2016/077690, filed on Mar. 29, 2016, which is based on and claims priority to and benefits of Chinese Patent Application No. 201510373311.7, filed with the State Intellectual Property Office (SIPO) of the People's Republic of China on Jun. 30, 2015. The entire contents of the above-identified applications are incorporated herein by reference.

### TECHNICAL FIELD

The present disclosure relates to the technical field of photovoltaic batteries, and particularly to a silicone composition, a reflective coating and a preparation method therefor, and a photovoltaic assembly comprising the reflective coating.

### BACKGROUND

Photovoltaic battery assembly (solar battery assembly) is a product that directly converts solar energy into electrical energy through a P—N junction by means of the photovoltaic effect of silicon and other semiconductors. In the photovoltaic battery assembly, when a back panel is made with a transparent material, a reflective coating is usually provided on the back panel to reflect the light transmitted onto the back panel back to the cell, so as to increase the solar energy utilization, thereby improving the overall performance of the assembly and ensuring a safe and stable operation of a photovoltaic power generation system.

At present, the reflective coating used in a photovoltaic battery assembly is generally formed by manually coating a one-component condensation-type silicone adhesive on a back plate and then subjecting to moisture curing. During use, the one-component condensation-type silicone adhesive can be cured under the action of moisture at room temperature without heating, and thus the process is simple. However, due to the limitations from the properties of the one-component condensation-type silicone adhesive per se, the following problems exist during use: (1) slow deep-section curing, where 24 hrs or more is needed for 5 mm curing; (2) high viscosity of the adhesive as a paste, where during use, the thickness is difficult to control, and the problems of difficult application, poor uniformity, and low efficiency exist when the position to be coated is irregular; and (3) release of small molecules upon curing, where if remaining in the coating, the small molecules will affect the coating performance.

To overcome the above problems, attempts are made by the researchers to use a two-component silicone adhesive with a fast curing rate. However, the bonding strength of the two-component silicone adhesive is often far below that of the one-component condensation-type silicone adhesive. This causes delamination of the reflective coating, thus being not conducive to the production and application.

### SUMMARY

An object of the present disclosure is to provide a silicone composition, a reflective coating and a preparation method therefor, and a photovoltaic assembly comprising the reflective coating, so as to reduce the curing time of the reflective coating prepared with the silicone composition and increase the adhesion force of the reflective coating.

To achieve the above object, in a first aspect of the present disclosure, a silicone composition is provided, which comprises a base polymer component, a catalyst, a cross-linking agent, and reflective particles. The base polymer component, the catalyst and the cross-linking agent are not mixed simultaneously before use. The base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds. The cross-linking agent is a polyorganosiloxane having at least two Si—H bonds.

In a second aspect of the present disclosure, a reflective coating is provided, which is formed by curing the silicone composition after mixing.

In a third aspect of the present disclosure, a method for preparing the reflective coating is provided, which comprises the steps of: mixing a portion of a base polymer component, a portion of reflective particles, an optional mechanical functional filler, and a catalyst under a first stirring condition, to obtain a mixed component A; mixing the remaining base polymer component, the remaining reflective particles, the optional mechanical functional filler, a cross-linking agent, an optional inhibitor, and an optional tackifier under a second stirring condition, to obtain a mixed component B; mixing the mixed component A and the mixed component B with stirring, to obtain a pre-material having a viscosity of 6000-10000 CP; and applying the pre-material onto a substrate, and curing under a curing condition, to form a reflective coating. The base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds. The cross-linking agent is a polyorganosiloxane having at least two Si—H bonds.

In the silicone composition, and the reflective coating and the preparation method therefor provided in the technical solutions of the present invention, by using a liquid polysiloxane having at least two Si-Vi bonds per molecule, a hydrogenated epoxy resin or cycloaliphatic epoxy resin-modified polymethylvinylsiloxane terminated with a hydroxyl group, and a siloxane resin having at least two Si-Vi bonds as a base polymer component, and a polyorganosiloxane having at least two Si—H bonds as a cross-linking agent, a silicone adhesive composition with a much more suitable bonding strength can be obtained. By means of the silicone adhesive composition, the curing time is reduced and the adhesion force of a reflective coating prepared therewith is increased. Meanwhile, in the silicone adhesive composition, a high proportion of a reflective material can be mixed to obtain a high reflectivity, thereby improving the solar energy utilization of a photovoltaic assembly containing the reflective coating prepared therefrom.

Other features and advantages of the present disclosure will be described in detail in the following detailed description.

### DETAILED DESCRIPTION

Hereinafter, specific embodiments of the present disclosure will be described in detail. It is to be understood that the specific embodiments described herein are provided merely for the purpose of illustration and explanation and not intended to limit the scope of the present disclosure.

The term “Vi” as used herein refers to vinyl, the “Si-Vi bond” refers to a linkage formed by a silicon atom with a vinyl group, and the “Si—H” refers to a linkage formed by a silicon atom with a hydrogen atom.

As is pointed out in the prior art, during the preparation of a reflective coating, problems exist that the one-component condensation-type silicone adhesive has a large viscosity, and is slow in deep-section curing and difficult in application, and the two-component silicone adhesive generally has a low viscosity and tends to delaminate. To overcome these problems, the present invention provides a silicone composition. The silicone composition comprises a base polymer component, a catalyst, a cross-linking agent and reflective particles. The base polymer component, the catalyst and the cross-linking agent are not mixed simultaneously before use. The base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds. The cross-linking agent is a polyorganosiloxane having at least two Si—H bonds.

The present disclosure relates to the above-mentioned silicone composition, and a reflective coating and a preparation method therefor. By using a liquid polysiloxane having at least two Si-Vi bonds per molecule, a hydrogenated epoxy resin or cycloaliphatic epoxy resin-modified polymethylvinylsiloxane terminated with a hydroxyl group, and a siloxane resin having at least two Si-Vi bonds as a base polymer component, and a polyorganosiloxane having at least two Si—H bonds as a cross-linking agent, a silicone adhesive composition with a much more suitable bonding strength can be obtained. By means of the silicone adhesive composition, the curing time is reduced and the adhesion force of a reflective coating prepared therewith is increased. Meanwhile, in the silicone adhesive composition, a high proportion of a reflective material can be mixed to obtain a high reflectivity, thereby improving the solar energy utilization of a photovoltaic assembly containing a reflective coating prepared therefrom.

For the purpose of adjusting the viscosity of a silicone adhesive formed after mixing the silicone composition and increasing the reaction rate of the silicone adhesive, in an optional embodiment of the present invention, the silicone composition comprises a component A and a component B, where the component A at least comprises a portion of the base polymer component, and the catalyst, and the component B at least comprises the remaining portion of the base polymer component, and the cross-linking agent. By dividing the silicone composition into the component A and the component B and then mixing the component A and the component B to form a silicone adhesive, the viscosity of the silicone adhesive can be adjusted, whereby the prepared silicone adhesive has a processability that allows it to be applied onto a back panel by screen printing.

Optionally, in the silicone composition, the component A comprises 45-55 parts by weight of the polymethylsiloxane having at least two Si-Vi bonds per molecule; 2.5-7.5 parts by weight of the hydrogenated epoxy resin or cycloaliphatic epoxy resin-modified polymethylvinylsiloxane terminated with a hydroxyl group; 5-10 parts by weight of the siloxane resin having at least two Si-Vi bonds; 0.015-0.075 parts by weight of the catalyst; and 1.5-5 parts by weight of the reflective particles; and the component B comprises 45-55 parts by weight of the polymethylsiloxane having at least two Si-Vi bonds per molecule; 2.5-7.5 parts by weight of the hydrogenated epoxy resin or cycloaliphatic epoxy resin-modified polymethylvinylsiloxane terminated with a hydroxyl group; 5-10 parts by weight of the siloxane resin having at least two Si-Vi bonds; 0.75-10 parts by weight of the polyorganosiloxane cross-linking agent having at least two Si—H bonds; and 1.5-5 parts by weight of the reflective particles.

In the silicone composition provided in the present disclosure, the raw materials used are not particularly limited, and the effects mentioned in the present disclosure can be achieved as long as the polymethylsiloxane and the siloxane resin have the required Si-Vi bonds, the polyorganosiloxane cross-linking agent has the required Si—H bonds, and the polymethylvinylsiloxane terminated with a hydroxyl group is modified with a hydrogenated epoxy resin or a cycloaliphatic epoxy resin. However, to further optimize the processability and usability of the silicone adhesive formed after mixing the silicone composition, the raw materials in the silicone composition may be suitably selected, specifically as described below.

Optionally, the polymethylsiloxane having at least two Si-Vi bonds per molecule used in the silicone composition has a vinyl content of 0.02-0.8 wt. %, and a viscosity of 200-500,000 CP. The viscosity of the silicone composition can be adjusted by controlling the vinyl (Vi) content in the polymethylsiloxane having at least two Si-Vi bonds, thereby controlling the coatability and the coating thickness of the silicone adhesive.

The polymethylsiloxane having at least two Si-Vi bonds per molecule used in the present disclosure includes, but is not limited to, at least one of α,ω-divinyl polydimethyl siloxane and vinyldimethylsiloxy capped polydimethylmethylvinylsiloxane.

The polymethylsiloxane having at least two Si-Vi bonds per molecule useful in the present disclosure may be a commercially available product, or be synthesized according to a conventional synthesis process. Commercially available products that may be used include, but are not limited to, α,ω-divinyl polydimethyl siloxane (vinyl content: 0.1-0.4 wt. %, and viscosity at 25° C.: 500-10000 CP) and vinyldimethylsiloxy capped polydimethylmethylvinylsiloxane (vinyl content: 0.5-2.0 wt. %, and viscosity at 25° C.: 200-15000 CP) commercially available from AB Specialty Silicones Co., Ltd; α,ω-divinyl polydimethyl siloxane (vinyl content: 0.12-0.42 wt. %, and viscosity at 25° C.: 500-10000 CP) commercially available from Zhejiang Runhe Co., Ltd; or α,ω-divinyl polydimethyl siloxane (vinyl content: 0.15-0.45 wt. %, and viscosity at 25° C.: 500-10000 CP) commercially available from Ant Co., Ltd.

Optionally, in the silicone composition, the hydrogenated epoxy resin or cycloaliphatic epoxy resin-modified polymethylvinylsiloxane terminated with a hydroxyl group is a modified product formed through the polymerization reaction of a hydrogenated epoxy resin or a cycloaliphatic epoxy resin with a methylvinyl polysiloxane terminated with a hydroxyl group, at a weight ratio of 1:0.5-2.5. The proportion of the epoxy resin in the whole coating is can be controlled by adjusting the weight ratio of the epoxy resin to the methylvinyl polysiloxane terminated with a hydroxyl group in the hydrogenated epoxy resin or cycloaliphatic epoxy resin-modified polymethylvinylsiloxane terminated with a hydroxyl group, thereby improving of the bonding strength of the coating.

The hydrogenated epoxy resin or cycloaliphatic epoxy resin-modified polymethylvinylsiloxane terminated with a hydroxyl group used in the present disclosure may be a commercially available product, or be synthesized according to a conventional synthesis process. In an optional embodiment of the present disclosure, a method for synthesizing the hydrogenated epoxy resin or cycloaliphatic epoxy resin-modified polymethylvinylsiloxane terminated with a hydroxyl group comprises: reacting a hydrogenated epoxy resin or a cycloaliphatic epoxy resin with a methylvinyl polysiloxane terminated with a hydroxyl group for 6-12 hrs at 100-150° C. in the presence of a catalyst (e.g. triphenylphosphine), to obtain a reaction product.

During the synthesis of the hydrogenated epoxy resin or cycloaliphatic epoxy resin-modified polymethylvinylsiloxane terminated with a hydroxyl group, hydrogenated epoxy resins that may be used include, but are not limited to, hydrogenated bisphenol A epoxy resin and/or hydrogenated bisphenol F epoxy resin. Optionally, the hydrogenated epoxy resin or cycloaliphatic epoxy resin has an epoxy equivalent of 130-250. When the epoxy equivalent is controlled to fall within the above-mentioned range, the functional group content in the hydrogenated epoxy resin or cycloaliphatic epoxy resin can be ensured, and the product is ensured to be in a flowing state at normal temperature.

Optionally, the vinyl (Vi) content of the siloxane resin having at least two Si-Vi bonds in the silicone composition is 0.5-1.5 wt. %. By defining the Vi content of the siloxane resin having at least two Si-Vi bonds in such a range, the compatibility between the resin and the silicone can be ensured, and the strength and toughness of the coating can be optimized to allow them to reach a balance. Optionally, the siloxane resin having at least two Si-Vi bonds comprises SiO_{4/2} and one or more of R₁SiO_{3/2}, R₂SiO_{2/2} and R₃SiO_{1/2}, where R₁, R₂, and R₃ may be the same or different and is Me (CH₃-, methyl) or Vi (vinyl). The silicone resin having at least two Si-Vi bonds and comprising the above-mentioned structure can promote the polymerization reaction of the siloxane resin, thereby improving the coating strength.

The siloxane resin having at least two Si-Vi bonds used in the present invention includes, but is not limited to, MQ silicone resin, MDQ silicone resin, and MTQ silicone resin.

The MQ silicone resin comprises a monofunctional silicon-oxygen unit (M, R₃SiO_{1/2}, where R₃ is methyl or vinyl) and a tetrafunctional silicon-oxygen unit (Q, SiO_{4/2}), for example, an MQ silicone resin with an M/Q ratio of 0.6-0.9, such as, VQM60 MQ silicone resin (vinyl content: 0.54%, and M/Q=0.6) commercially available from AB Specialty Silicones Co., Ltd, and XB-82063 MQ silicone resin (vinyl content: 1-4%, and M/Q=0.6-0.9) commercially available from Xibo Chemical Technology Co., Ltd.

The MDQ silicone resin comprises a monofunctional silicon-oxygen unit (M, R₃SiO_{1/2}, where R is methyl or vinyl), a difunctional silicon-oxygen unit (D, R₂SiO_{2/2}, where R is methyl or vinyl), and a tetrafunctional silicon-oxygen unit (Q, SiO_{4/2}).

The MTQ silicone resin comprises a monofunctional silicon-oxygen unit (M, R₃SiO_{1/2}, where R is methyl or vinyl), a trifunctional silicon-oxygen unit (T, R₁SiO_{3/2}, where R is methyl or vinyl), and a tetrafunctional silicon-oxygen unit (Q, SiO_{4/2}).

Optionally, the hydrogen content of the polyorganosiloxane cross-linking agent having at least two Si—H bonds in the silicone composition is 0.1-1 wt. %. In the present disclosure, the mechanical performance and the reaction rate of the adhesive layer are controlled by adjusting the hydrogen content of the cross-linking agent.

The polyorganosiloxane having at least two Si—H bonds used in the present disclosure includes, but is not limited to, at least one of trimethylsiloxy capped dimethylmethylhydrogen polysiloxane and Si—H dimethyl capped dimethylmethylhydrogen polysiloxane.

Optionally, the catalyst used in the silicone composition can be selected according to the reaction principle, and includes, but is not limited to, nickel, palladium, osmium, iridium, platinum and other transition metal compounds. Optionally, the catalyst is a platinum catalyst, and the use of a platinum catalyst can facilitate the acquisition of a suitable curing rate. For example, the platinum catalyst is a platinum-vinyl siloxane complex, in which the platinum content is 500-5000 ppm. The curing rate is controlled by using a platinum-vinyl siloxane complex and adjusting the platinum content.

Optionally, the reflective particles used in the silicone composition include, but are not limited to, reflective glass microspheres. Reflective glass microspheres having a particle size of 0.5 to 3 μm can be used. The use of reflective glass microspheres having a particle size of 0.5 to 3 μm is advantageous in that the reflective glass microspheres are more uniformly dispersed, thus achieving a better reflection effect, thereby improving the reflectivity, and further improving the solar energy utilization.

In the silicone composition, to adjust the service life of the coating prepared, an inhibitor may be further comprised. In an optional embodiment of the present disclosure, the silicone composition further comprises, based on 100 parts by weight of the polymethylsiloxane having at least two Si-Vi bonds per molecule, 0.002-0.005 parts by weight of an inhibitor. Optionally, when the silicone composition comprises a component A and a component B, the inhibitor is mixed in the component B.

The inhibitor used in the present disclosure includes, but is not limited to, one or more of 2-methyl-3-butyn-2-ol, 2-phenyl-3-butyn-2-ol, 3,5-dimethyl-1-hexyn-3-ol, 1-hexyn-1-cyclohexanol, 3-ethyl-3-buten-1-yne, 1,3-divinyl tetramethyldisiloxane, 1,3,5,7-tetravinyltetramethylcyclotetarsiloxane, 1,3-divinyl tetramethyldisiloxane, methyl tris(3-methyl-1-butyn-3-oxy)silane, tetramethylethylenediamine, benzotriazole, triphenylphosphine, and malaic acid derivatives. For example, an alkyne inhibitor is used.

In the silicone composition, to ensure the retention of the bonding strength of the silicone adhesive after aging, a tackifier may be further comprised. In an optional embodiment of the present disclosure, the silicone composition further comprises, based on 100 parts by weight of the polymethylsiloxane having at least two Si-Vi bonds per molecule, 0.05-0.3 parts by weight of a tackifier. Optionally, when the silicone composition comprises a component A and a component B, the tackifier is mixed in the component B. In the present disclosure, the tackifier can be prevented from reacting with the raw materials in the component A in advance by mixing the tackifier and the cross-linking agent together in the component B.

Optionally, the tackifier is one or more selected from vinyltriethoxysilane, acryloylpropyltrimethoxysilane, alkylacryloylpropyltrimethoxysilane, allyltriethoxysilane, epoxypropoxypropyltrimethoxysilane, allylglycidyl ether, an adduct of siloxane having a Si—H bond with allylglycidyl ether or methylacryloyloxy propyltrimethoxysilane, and a polycondensate prepared by cohydrolysis of trimethoxysilane with allyltrimethoxysilane.

In the silicone composition, to further increase the mechanical performance and the bonding property of the adhesive layer, a mechanical functional filler may be further comprised. In an optional embodiment of the present disclosure, the silicone composition further comprises, based on 100 parts by weight of the polymethylsiloxane having at least two Si-Vi bonds per molecule, 5-20 parts by weight of a mechanical functional filler. Optionally, when the silicone composition comprises a component A and a component B, the component A comprises 6-10 parts by weight of the mechanical functional filler, and the component B comprises 6-10 parts by weight of the mechanical functional filler. By mixing the mechanical functional filler respectively in the component A and the component B, the mechanical functional filler can be more uniformly mixed with other raw materials, thereby enhancing the uniformity of the mechanical performance and the bonding property of the adhesive layer.

Optionally, the mechanical functional filler is a hydrophobically treated filler particle. Optionally, the filler particle is one or more of white carbon black (gas-phase method white carbon black), activated calcium carbonate, fine silica powder, diatomaceous earth and titanium dioxide (titanium dioxide powder, and gas-phase method titanium dioxide). In the present disclosure, the addition of the above filler can improve the mechanical performance and the bonding property of the adhesive layer. Optionally, the filler particle has a particle size of 0.5-3 μm.

In the present disclosure, a reflective coating is further provided, which is formed by mixing and then curing the silicone composition. The reflective coating provided in the present disclosure is prepared with the silicone composition, and has excellent adhesion performance and excellent reflectivity, thereby facilitating the improvement of the solar energy utilization.

In the present disclosure, a method for preparing the reflective coating is further provided. The preparation method comprises the steps of: mixing a portion of a base polymer component, a portion of reflective particles, an optional mechanical functional filler, and a catalyst under a first stirring condition, to obtain a mixed component A; mixing the remaining base polymer component, the remaining reflective particles, the optional mechanical functional filler, a cross-linking agent, an optional inhibitor, and an optional tackifier under a second stirring condition, to obtain a mixed component B; mixing the mixed component A and the mixed component B with stirring, to obtain a pre-material having a viscosity of 6000-10000 CP; and applying the pre-material onto a substrate, followed by curing under a curing condition, to form the reflective coating. The base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds. The cross-linking agent is a polyorganosiloxane having at least two Si—H bonds.

For saving energy, in an optional embodiment, the steps of preparing the mixed component A and the mixed component B in the method for preparing the reflective coating comprises bringing the base polymer component, the reflective particles and the optional mechanical functional filler into contact and mixing them in proportion with stirring (high-speed stirring at 2000-7000 rpm for 20-40 min), to obtain a mixture, and dividing the mixture into a mixture A and a mixture B; mixing the mixture A with the catalyst, to obtain the mixed component A; and mixing the mixture B with the cross-linking agent, the optional inhibitor, and the optional tackifier, to obtain the mixed component B.

Optionally, in the preparation method, the first stirring condition and the second stirring condition both comprise high-speed stirring at 2000-7000 rpm for 20-40 min; and the curing condition comprises baking at 120-150° C. for 5-15 min.

Optionally, the preparation method further comprises steps of grinding the respective mixture before the step of mixing the mixed component A and the mixed component B with stirring. Optionally, the grinding condition comprises grinding 2-3 times in a three-roller grinding mill with an inter-roller gap of 20-35 μm, to obtain a mixed component having a fineness of 20-35 μm.

In the present disclosure, a photovoltaic assembly is further provided, which comprises a back panel and a reflective coating covering the back panel, where the reflective coating is a reflective coating as described above. By using the above-mentioned reflective coating having good adhesion force and reflectivity, the service life of the photovoltaic assembly is prolonged and the solar energy utilization is enhanced.

The beneficial effects of the present disclosure will be further described below in connection with specific examples and comparative examples (in the following examples, the raw materials are each added in parts by weight).

### EXAMPLE 1

(I) Preparation of the Hydrogenated Epoxy Resin-Modified Polymethylvinylsiloxane Terminated with a Hydroxyl Group

100 parts of hydrogenated bis-phenol A epoxy resin (EPALLOY 5000 commercially available from CVC Corp., epoxy equivalent: 230) was reacted with 70 parts of methylvinyl polysiloxane terminated with a hydroxyl group (DA30 commercially available from AB Specialty Silicones Co., Ltd, vinyl content: 0.6%) at 120° C. for 9 hrs in the presence of triphenylphosphine as a catalyst, to obtain a reaction product.

(II) Material Mixing of the Component A and the Component B in the Silicone Composition

Mixing of the component A: 100 parts of α,ω-divinyl polydimethyl siloxane (VS5000 commercially available from AB Specialty Silicones Co., Ltd, vinyl content: 0.16%, and viscosity (at 25° C.): 5000 CP), 10 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 10 parts of titanium dioxide powder (particle size: 1 μm), 2 parts of fumed silica (particle size: 0.5 μm), 10 parts of reflective glass microspheres (particle size: 2 μm), and 0.04 parts of Kaarst platinum catalyst (SYC-off 4000 catalyst commercially available from Dow Corning, in which the content of platinum is 0.5 wt %) were stirred for 30 min at a rotation speed of 500 rpm, and then ground two times in a three-roller grinding mill (grinding parameter: inter-roller gap 30 μm), to obtain the component A having a fineness of 22 μm.

Mixing of the component B: 97.09 parts of α,ω-divinyl polydimethyl siloxane (VS5000 commercially available from AB Specialty Silicones Co., Ltd, vinyl content: 0.16%, and viscosity (at 25° C.): 5000 CP), 10 parts of the hydrogenated epoxy resin-modified polymethylvinylsiloxane terminated with a hydroxyl group, 10 parts of MDQ silicone resin (vinyl content: 0.5%, and M/D/Q=3/3/4), 10 parts of titanium dioxide powder (particle size: 1 μm), 2 parts of fumed silica (particle size: 0.5 μm), 10 parts of reflective glass microspheres (particle size: 2 μm), 2.8 parts of Si—H dimethyl capped dimethylmethylhydrogen polysiloxane (XL10 commercially available from AB Specialty Silicones Co., Ltd, hydrogen content: 0.75 wt. %), 0.005 parts of 1-hexyn-1-cyclohexanol, and 0.15 parts of epoxypropxypropyltrimethoxysilane were stirred for 30 min at a rotation speed of 500 rpm, and then ground two times in a three-roller grinding mill (grinding parameter: inter-roller gap 30 μm), to obtain the component B having a fineness of 25 μm.

(III) Preparation of the Reflective Coating

The component A and the component B were uniformly mixed at a weight ratio of 1:1, to obtain a mixture having a viscosity of 7800 CP. The uniformly mixed silicone composition was printed onto a site of a back panel where reflection was needed by using a 100-mesh screen printing machine and then baked at 150° C. for 10 min to form a reflective coating.

### EXAMPLE 2

(I) Preparation of the Hydrogenated Epoxy Resin-Modified Polymethylvinylsiloxane Terminated with a Hydroxyl Group

100 parts of hydrogenated bis-phenol A epoxy resin (EPALLOY 5000 commercially available from CVC Corp., epoxy equivalent: 230) was reacted with 200 parts of methylvinyl polysiloxane terminated with a hydroxyl group (DA30 commercially available from AB Specialty Silicones Co., Ltd, vinyl content: 0.6%) at 120° C. for 9 hrs in the presence of triphenylphosphine as a catalyst, to obtain a reaction product.

(II) Material Mixing of the Component A and the Component B in the Silicone Composition

Mixing of the component A: 81 parts of vinyldimethylsiloxy capped polydimethyl siloxane (RH301 commercially available from Runhe Co., Ltd, vinyl content: 0.04%, and viscosity (at 25° C.): 100000CP), 19 parts of vinyldimethylsiloxy capped polydimethyl siloxane (VS200 commercially available from AB Specialty Silicones Co., Ltd, vinyl content: 0.675%, and viscosity (at 25° C.): 200 CP), 10 parts of the hydrogenated epoxy resin-modified polymethylvinylsiloxane terminated with a hydroxyl group, 10 parts of MQ silicone resin (XB-82062 commercially available from Xibo Chemical Technology Co., Ltd, vinyl content: 4%, and M/Q=0.6), 10 parts of titanium dioxide powder (particle size: 1 μm), 2 parts of fumed silica (particle size: 0.5 μm), 10 parts of reflective glass microspheres (particle size: 2 μm), and 0.04 parts of Kaarst platinum catalyst (SYC-off 4000 commercially available from Dow Corning, in which the content of platinum is 0.5%) were stirred for 30 min at a rotation speed of 500 rpm, and then ground two times in a three-roller grinding mill (grinding parameter: inter-roller gap 30 μm), to obtain the component A having a fineness of 25 μm.

Mixing of the component B: 75 parts of vinyldimethylsiloxy capped polydimethyl siloxane (RH301 commercially available from Runhe Co., Ltd, vinyl content: 0.04%, and viscosity (at 25° C.): 100000 CP), 17.62 parts of vinyldimethylsiloxy capped polydimethyl siloxane (VS200 commercially available from AB Specialty Silicones Co., Ltd, vinyl content: 0.675%, and viscosity (at 25° C.): 200 CP), 10 parts of the hydrogenated epoxy resin-modified polymethylvinylsiloxane terminated with a hydroxyl group, 10 parts of MQ silicone resin (XB-82062 commercially available from Xibo Chemical Technology Co., Ltd, vinyl content: 4%, and M/Q=0.6), 10 parts of titanium dioxide powder (particle size: 1 μm), 2 parts of fumed silica (particle size: 0.5 μm), 10 parts of reflective glass microspheres (particle size: 2 μm), 7.16 parts of Si—H dimethyl capped dimethylmethylhydrogen polysiloxane (XL10 commercially available from AB Specialty Silicones Co., Ltd, hydrogen content: 0.75 wt. %)), 0.005 parts of 1-hexyn-1-cyclohexanol, and 0.15 parts of epoxypropxypropyltrimethoxysilane were stirred for 30 min at a rotation speed of 500 rpm, and then ground two times in a three-roller grinding mill (grinding parameter: inter-roller gap 30 μm), to obtain the component B having a fineness of 24 μm.

(III) Preparation of the Reflective Coating

The component A and the component B were uniformly mixed at a weight ratio of 1:1, to obtain a mixture having a viscosity of 9600 CP. The uniformly mixed silicone composition was printed onto a site of a back panel where reflection was needed by using a 100-mesh screen printing machine and then baked at 150° C. for 10 min to form a reflective coating.

### EXAMPLE 3

(I) Preparation of the Hydrogenated Epoxy Resin-Modified Polymethylvinylsiloxane Terminated with a Hydroxyl Group: The Preparation Method was the Same as the Method for Preparing the Epoxy Resin-Modified Polymethylvinylsiloxane Terminated with a Hydroxyl Group as Described in Example 2.

(II) Material Mixing of the Component A and the Component B in the Silicone Composition

Mixing of the component A: 100 parts of α,ω-divinyl polydimethyl siloxane (VS5000 commercially available from AB Specialty Silicones Co., Ltd, vinyl content: 0.16%, and viscosity (at 25° C.): 5000 CP), 10 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 10 parts of titanium dioxide powder (particle size: 0.2 μm), 2 parts of fumed silica (particle size: 0.3 μm), 10 parts of reflective glass microspheres (particle size: 1.5 μm), 10 parts of reflective glass microspheres (particle size: 1.5 μm), and 0.04 parts of Kaarst platinum catalyst (SYC-off 4000 commercially available from Dow Corning, in which the content of platinum is 0.5%) were stirred for 30 min at a rotation speed of 500 rpm, and then ground two times in a three-roller grinding mill (grinding parameter: inter-roller gap 30 μm), to obtain the component A having a fineness of 25 μm.

Mixing of the component B: 94.4 parts of α,ω-divinyl polydimethyl siloxane (VS5000 commercially available from AB Specialty Silicones Co., Ltd, vinyl content: 0.16%, and viscosity (at 25° C.): 5000 CP), 10 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 10 parts of titanium dioxide powder (particle size: 0.2 μm), 2 parts of fumed silica (particle size: 0.3 μm), 10 parts of reflective glass microspheres (particle size: 1.5 μm), 4.6 parts of Si—H dimethyl capped dimethylmethylhydrogen polysiloxane (XB-711 commercially available from Xibo Chemical Technology Co., Ltd, hydrogen content: 0.45 wt. %), 0.005 parts of 1-hexyn-1-cyclohexanol, and 0.15 parts of epoxypropxypropyltrimethoxysilane were stirred for 30 min at a rotation speed of 500 rpm, and then ground two times in a three-roller grinding mill (grinding parameter: inter-roller gap 30 μm), to obtain the component B having a fineness of 25 μm.

(III) Preparation of the Reflective Coating

The component A and the component B were uniformly mixed at a weight ratio of 1:1, to obtain a mixture having a viscosity of 7800 CP. The uniformly mixed silicone composition was printed onto a site of a back panel where reflection was needed by using a 100-mesh screen printing machine and then baked at 150° C. for 10 min to form a reflective coating.

### EXAMPLE 4

(I) Preparation of the Hydrogenated Epoxy Resin-Modified Polymethylvinylsiloxane Terminated with a Hydroxyl Group

100 parts of hydrogenated bis-phenol Aepoxy resin (YL6753 commercially available from Shanghai Zhongshi Co., Ltd., epoxy equivalent: 180) was reacted with 255 parts of methylvinyl polysiloxane terminated with a hydroxyl group (DA30 commercially available from AB Specialty Silicones Co., Ltd, vinyl content: 0.6%) at 120° C. for 9 hrs in the presence of triphenylphosphine as a catalyst, to obtain a reaction product.

(II) Material Mixing of the Component A and the Component B in the Silicone Composition

Mixing of the component A: 80 parts of α,ω-divinyl polydimethyl siloxane (VS2000 commercially available from AB Specialty Silicones Co., Ltd, vinyl content: 0.2%, and viscosity (at 25° C.): 2000 CP), 20 parts of vinyldimethylsiloxy capped polydimethylmethylvinyl siloxane (VDM65000 commercially available from AB Specialty Silicones Co., Ltd, vinyl content: 3.5%), 10 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 10 parts of titanium dioxide powder (particle size: 0.5 μm), 2 parts of fumed silica (particle size: 0.2 μm), 10 parts of reflective glass microspheres (particle size: 1.5 μm), 0.04 parts of Kaarst platinum catalyst (SYC-off 4000 commercially available from Dow Corning, in which the content of platinum is 0.5%) were stirred for 30 min at a rotation speed of 500 rpm, and then ground two times in a three-roller grinding mill (grinding parameter: inter-roller gap 30 μm), to obtain the component A having a fineness of 24 μm.

Mixing of the component B: 77.6 parts of α,ω-divinyl polydimethyl siloxane (VS2000 commercially available from AB Specialty Silicones Co., Ltd, vinyl content: 0.2%, and viscosity (at 25° C.): 2000 CP), 22.4 parts of vinyldimethylsiloxy capped polydimethylmethylvinyl siloxane (VDM65000 commercially available from AB Specialty Silicones Co., Ltd, vinyl content: 3.5%), 10 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 10 parts of titanium dioxide powder (particle size: 0.5 μm), 2 parts of fumed silica (particle size: 0.2 μm), 10 parts of reflective glass microspheres (particle size: 1.5 μm), 22.3 parts of Si—H dimethyl capped dimethylmethylhydrogen polysiloxane (XL13 commercially available from AB Specialty Silicones Co., Ltd, hydrogen content 0.38 wt. %), 0.005 parts of 1-hexyn-1-cyclohexanol, and 0.15 parts of epoxypropxypropyltrimethoxysilane were stirred for 30 min at a rotation speed of 500 rpm, and then ground two times in a three-roller grinding mill (grinding parameter: inter-roller gap 30 μm), to obtain the component B having a fineness of 25 μm.

(III) Preparation of the Reflective Coating

The component A and the component B were uniformly mixed at a weight ratio of 1:1, to obtain a mixture having a viscosity of 8100 CP. The uniformly mixed silicone composition was printed onto a site of a back panel where reflection was needed by using a 100-mesh screen printing machine and then baked at 150° C. for 10 min to form a reflective coating.

### EXAMPLE 5

(I) Preparation of the Hydrogenated Epoxy Resin-Modified Polymethylvinylsiloxane Terminated with a Hydroxyl Group: The Preparation Method was the Same as the Method for Preparing the Hydrogenated Epoxy Resin-Modified Polymethylvinylsiloxane Terminated with a Hydroxyl Group as Described in Example 1.

(II) Material Mixing of the Component A and the Component B in the Silicone Composition

Mixing of the component A: 100 parts of α,ω-divinyl polydimethyl siloxane (VS5000 commercially available from AB Specialty Silicones Co., Ltd, vinyl content: 0.16%, and viscosity (at 25° C.): 5000 CP), 15 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 15 parts of titanium dioxide powder (particle size: 1 μm), 3 parts of fumed silica (particle size: 0.5 μm), 3 parts of reflective glass microspheres (particle size: 2 μm), and 0.12 parts of Kaarst platinum catalyst (SYC-off 4000 commercially available from Dow Corning, in which the content of platinum is 0.5%) were stirred for 30 min at a rotation speed of 500 rpm, and then ground two times in a three-roller grinding mill (grinding parameter: inter-roller gap 30 μm), to obtain the component A having a fineness of 22 μm.

Mixing of the component B: 97.07 parts of α,ω-divinyl polydimethyl siloxane (VS5000 commercially available from AB Specialty Silicones Co., Ltd, vinyl content: 0.16%, and viscosity (at 25° C.): 5000 CP), 15 parts of the hydrogenated epoxy resin-modified polymethylvinylsiloxane terminated with a hydroxyl group, 10 parts of MQ silicone resin (VQM60 commercially available from AB Specialty Silicones Co., Ltd, vinyl content: 0.5%, and M/Q=0.65), 15 parts of titanium dioxide powder, 3 parts of fumed silica, 3 parts of reflective glass microspheres, 5.66 parts of Si—H capped polydimethylmethylhydrogen polysiloxane (XL10 commercially available from AB Specialty Silicones Co., Ltd, hydrogen content 0.75 wt. %), 0.005 parts of ethynylcyclohexanol, and 0.15 parts of epoxypropxypropyltrimethoxysilane were stirred for 30 min at a rotation speed of 500 rpm, and then ground two times in a three-roller grinding mill (grinding parameter: inter-roller gap 30 μm), to obtain the component B having a fineness of 22 μm.

(III) Preparation of the Reflective Coating

The component A and the component B were uniformly mixed at a weight ratio of 1:1, to obtain a mixture having a viscosity of 8500 CP. The uniformly mixed silicone composition was printed onto a site of a back panel where reflection was needed by using a 100-mesh screen printing machine and then baked at 120° C. for 15 min to form a reflective coating.

### EXAMPLE 6

(I) Preparation of the Hydrogenated Epoxy Resin-Modified Polymethylvinylsiloxane Terminated with a Hydroxyl Group: The Preparation Method was the Same as the Method for Preparing the Hydrogenated Epoxy Resin-Modified Polymethylvinylsiloxane Terminated with a Hydroxyl Group as Described in Example 1.

(II) Material Mixing of the Component A and the Component B in the Silicone Composition

Mixing of the component A: 103 parts of α,ω-divinyl polydimethyl siloxane (VS5000 commercially available from AB Specialty Silicones Co., Ltd, vinyl content: 0.16%, and viscosity (at 25° C.): 5000 CP), 5 parts of the hydrogenated epoxy resin-modified polymethylvinylsiloxane terminated with a hydroxyl group, 20 parts of MQ silicone resin (VQM60 commercially available from AB Specialty Silicones Co., Ltd, vinyl content: 0.5%, and M/Q=0.65), 8 parts of titanium dioxide powder (particle size: 1 μm), 2 parts of fumed silica (particle size: 0.5 μm), 10 parts of reflective glass microspheres (particle size: 2 μm), and 0.16 parts of Kaarst platinum catalyst (SYC-off 4000 commercially available from Dow Corning, in which the content of platinum is 0.5%) were stirred for 30 min at a rotation speed of 500 rpm, and then ground two times in a three-roller grinding mill (grinding parameter: inter-roller gap 40 μm), to obtain the component A having a fineness of 25 μm.

Mixing of the component B: 97.07 parts of α,ω-divinyl polydimethyl siloxane (VS5000 commercially available from AB Specialty Silicones Co., Ltd, vinyl content: 0.16%, and viscosity (at 25° C.): 5000 CP), 5 parts of the hydrogenated epoxy resin-modified polymethylvinylsiloxane terminated with a hydroxyl group, 20 parts of MQ silicone resin (VQM60 commercially available from AB Specialty Silicones Co., Ltd, vinyl content: 0.5%, and M/Q=0.65), 8 parts of titanium dioxide powder (particle size: 1 μm), 2 parts of fumed silica (particle size: 0.5 μm), 6 parts of reflective glass microspheres (particle size: 2 μm), 5.66 parts of Si—H capped polydimethylmethylhydrogen siloxane (XL10 commercially available from AB Specialty Silicones Co., Ltd, hydrogen content: 0.75 wt. %), 0.007 parts of ethynylcyclohexanol, and 0.4 parts of epoxypropxypropyltrimethoxysilane were stirred for 30 min at a rotation speed of 500 rpm, and then ground two times in a three-roller grinding mill (grinding parameter: inter-roller gap 40 μm), to obtain the component B having a fineness of 25 μm.

(III) Preparation of the Reflective Coating

The component A and the component B were uniformly mixed at a weight ratio of 1:1, to obtain a mixture having a viscosity of 6500 CP. The uniformly mixed silicone composition was printed onto a site of a back panel where reflection was needed by using a 100-mesh screen printing machine and then baked at 150° C. for 8 min to form a reflective coating.

### EXAMPLE 7

(I) Preparation of the Cycloaliphatic Epoxy Resin-Modified Polymethylvinylsiloxane Terminated with a Hydroxyl Group: Reference was Made to the Method for Preparing the Hydrogenated Epoxy Resin-Modified Polymethylvinylsiloxane Terminated with a Hydroxyl Group as Described in Example 1, Except that an Cycloaliphatic Epoxy Resin (JE-8421 Commercially Available from Jiadida Co. Ltd., Epoxy Equivalent: 135) was Used in Place of the Hydrogenated Bis-Phenol Aepoxy Resin.

(II) Material Mixing of the Component A and the Component B in the Silicone Composition: The Material Mixing Methods were the Same as those of the Component A and the Component B in the Silicone Composition as Described in Example 1.

(III) Preparation of the Reflective Coating: The Reflective Coating was Prepared Following the Same Method as Described in Example 1.

### COMPARATIVE EXAMPLE 1

The method was as described in Example 1, except that no epoxy resin-modified polymethylvinylsiloxane terminated with a hydroxyl group was added in the components A and B.

### COMPARATIVE EXAMPLE 2

The method was as described in Example 1, except that no reflective glass microspheres were contained in the components A and B.

### COMPARATIVE EXAMPLE 3

### Reflective Coating Prepared with a One-Component Condensation-Type Silicone Adhesive

(I) Mixing of the Silicone Composition: 200 Parts by Weight of a One-Component Condensation-Type White Silicone Adhesive (1527 W One-Component Condensation-Type Silicone Adhesive Commercially Available from Tianshan Co. Ltd.) was Stirred with 20 Parts of Reflective Glass Microspheres (Particle Size: 2 μm) for 30 Min at a Rotation Speed of 500 RPM Under Vacuum.

(II) Preparation of Reflective Coating

The uniformly mixed silicone composition was coated onto a site of a back panel where reflection was needed by means of extrusion and knife coating, and stood for 48 hrs at room temperature to form a reflective coating.

### COMPARATIVE EXAMPLE 4

### Reflective Coating Prepared with a Two-Component Addition-Type Silicone Adhesive

(I) Mixing of the Silicone Composition: 200 Parts by Weight of a Two-Component Addition-Type Silicone Adhesive (TB0330 Two-Component Addition-Type Silicone Adhesive Commercially Available from Rainbow Adhesive Co., Ltd.) was Stirred with 20 Parts of Reflective Glass Microspheres (Particle Size: 2 μm) and 0.15 Parts of Epoxypropxypropyltrimethoxysilane for 30 Min at a Rotation Speed of 500 RPM, and then Ground 2 Times in a Three-Roller Grinding Mill (Grinding Parameter: Inter-Roller Gap 30 μm), to Obtain a Silicone Composition Having a Fineness of 25 μm.

(II) Preparation of Reflective Coating

The uniformly mixed silicone composition was printed onto a site of a back panel where reflection was needed by using a 100-mesh screen printing machine and then baked at 150° C. for 30 min to form a reflective coating.

The reflective coatings prepared in Examples 1 to 7 and Comparative Examples 1 to 4 were amenable to the following tests.

(I) Test Items and Methods
(1) Adhesion force: A corresponding reflective coating was formed on a glass surface (area: 50 mm*50 mm) with the silicone composition by using the method for preparing a reflective coating as described in Examples 1 to 7 and Comparative Examples 1 to 4, and then tested following GB/T 9286-1998.
(2) Adhesion force after 1000 hrs at double 85 (an environment with a temperature of 85° C. and a humidity of 85%): A corresponding reflective coating was formed on a glass surface (area: 50 mm*50 mm) with the silicone composition by using the method for preparing a reflective coating as described in Examples 1 to 7 and Comparative Examples 1 to 4, stood for 1000 hrs in an environment with a temperature of 85° C. and a humidity of 85%, and then removed for test following GB/T 9286-1998.
(3) Yellowing index

Testing Instrument: Yellowing Tester

Fabrication of test samples (at least three groups): A reflective coating of 0.15±0.05 mm in thickness was evenly coated onto a glass surface with the silicone composition by using the method for preparing a reflective coating as described in Examples 1 to 7 and Comparative Examples 1 to 4.

Testing index: ΔAb value (i.e., the yellowness index) of the coating. The difference between the b values before and after aging for 1000 hrs at double 85 (temperature 85° C. and 85% humidity), that is, Δb after 1000 hrs at double 85, was calculated.
(4) Reflectivity

Testing Instrument: Transmittance/Reflectivity Tester

Fabrication of test samples (at least three groups): A reflective coating of 0.15±0.05 mm in thickness was evenly coated onto a glass surface with the silicone composition by using the method for preparing a reflective coating as described in Examples 1 to 7 and Comparative Examples 1 to 4.

Testing index: uniformity in coating reflectivity. The ratio of the intensity of light reflected by the coating to the intensity of the light incident on the coating was measured.

(II) The Test Results are Shown in Table 1.

TABLE 1

| | | 1000 hrs | | |
|---|---|---|---|---|
| | | at double 85 | | |
| | Adhesion | Adhesion | Index | Reflectivity |
| | force | force | Δb | (%) |
| Example 1 | Grade 0 | Grade 0 | 0.46 | 92% |
| Example 2 | Grade 0 | Grade 0 | 0.45 | 92% |
| Example 3 | Grade 0 | Grade 0 | 0.42 | 92% |
| Example 4 | Grade 0 | Grade 0 | 0.44 | 92% |
| Example 5 | Grade 0 | Grade 0 | 0.43 | 93% |
| Example 6 | Grade 0 | Grade 0 | 0.44 | 91% |
| Example 7 | Grade 0 | Grade 0 | 0.42 | 92% |
| Comparative Example 1 | Grade 4 | Grade 5 | 0.4 | 92% |
| Comparative Example 2 | Grade 0 | Grade 0 | 0.6 | 65% |
| Comparative Example 3 | Grade 2 | Grade 3 | 0.7 | 72% |
| Comparative Example 4 | Grade 1 | Grade 2 | 0.8 | 69% |

As can be seen from the data in Table 2, by using a liquid polysiloxane having at least two Si-Vi bonds per molecule, an epoxy resin-modified polymethylvinylsiloxane terminated with a hydroxyl group, and a siloxane resin having at least two Si-Vi bonds as a base polymer component, and a polyorganosiloxane having at least two Si—H bonds as a cross-linking agent, a silicone adhesive composition with a much more suitable bonding strength can be obtained. By means of the silicone adhesive composition, the curing time is reduced and the adhesion force of a reflective coating prepared therewith is increased. Meanwhile, in the silicone adhesive composition, a high proportion of a reflective material can be mixed to obtain a high reflectivity, thereby improving the solar energy utilization of a photovoltaic assembly containing a reflective coating prepared therefrom.

While the present disclosure has been described in detail with reference to preferred embodiments hereinbefore, the present disclosure is not limited to particular details in the above-described embodiments. Various modifications made to the technical solution of the present disclosure without departing from the scope of the present disclosure fall within the protection scope of the present disclosure.

It is to be noted that the specific technical features described in the above detailed embodiments may be combined in any suitable manner without contradiction. To avoid unnecessary repetition, the various possible combinations are not further described in the present disclosure again.

In addition, various embodiments of the present disclosure may be combined in any way without departing from the spirit of the present disclosure, and such combinations are also embraced in the protection scope of the present disclosure.

What is claimed is:

1. A silicone composition, comprising a base polymer component, a catalyst, a cross-linking agent and reflective particles, wherein the base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds; and the cross-linking agent is a polyorganosiloxane having at least two Si—H bonds.

2. The silicone composition according to claim 1, wherein the silicone composition comprises a component A and a component B,
the component A comprises:
45-55 parts by weight of the polymethylsiloxane having at least two Si-Vi bonds per molecule;
2.5-7.5 parts by weight of the hydrogenated epoxy resin or cycloaliphatic epoxy resin-modified polymethylvinylsiloxane terminated with a hydroxyl group;
5-10 parts by weight of the siloxane resin having at least two Si-Vi bonds;
0.015-0.075 parts by weight of the catalyst; and
1.5-5 parts by weight of the reflective particles; and
the component B comprises:
45-55 parts by weight of the polymethylsiloxane having at least two Si-Vi bonds per molecule;
2.5-7.5 parts by weight of the hydrogenated epoxy resin or cycloaliphatic epoxy resin-modified polymethylvinylsiloxane terminated with a hydroxyl group;
5-10 parts by weight of the siloxane resin having at least two Si-Vi bonds;
0.75-10 parts by weight of the polyorganosiloxane cross-linking agent having at least two Si—H bonds; and
1.5-5 parts by weight of the reflective particles,
wherein the component A and the component B are formed separately.

3. The silicone composition according to claim 1, wherein the polymethylsiloxane having at least two Si-Vi bonds per molecule has a vinyl content of 0.02-0.8 wt. %, and a viscosity of 200-500,000 CP.

4. The silicone composition according to claim 1, wherein the hydrogenated epoxy resin terminated with a hydroxyl group is a modified product formed through the polymerization reaction of a hydrogenated epoxy resin with a methylvinyl polysiloxane terminated with a hydroxyl group, at a weight ratio of 1:0.5-2.5; and the cycloaliphatic epoxy resin-modified polymethylvinylsiloxane terminated with a hydroxyl group is a modified product formed through the polymerization reaction of a cycloaliphatic epoxy resin with a methylvinyl polysiloxane terminated with a hydroxyl group, at a weight ratio of 1:0.5-2.5.

5. The silicone composition according to claim 1, wherein the siloxane resin having at least two Si-Vi bonds has a vinyl content of 0.5-1.5 wt. %.

6. The silicone composition according to claim 5, wherein the siloxane resin having at least two Si-Vi bonds comprises SiO_{4/2} and one or more of R₁SiO_{3/2}, R₂SiO_{2/2} and R₃SiO_{1/2}, where R₁, R₂, and R₃ are selected from a group of Me and Vi.

7. The silicone composition according to claim 1, wherein the polyorganosiloxane having at least two Si—H bonds has a hydrogen content of 0.1-1 wt. %.

8. The silicone composition according to claim 1, wherein the catalyst is a platinum-vinyl siloxane complex, in which the platinum content is 500-5000 ppm.

9. The silicone composition according to claim 1, wherein the reflective particles are reflective glass microspheres having a particle size of 0.5-3 μm.

10. The silicone composition according to claim 2, wherein the silicone composition further comprises, based on 100 parts by weight of the polymethylsiloxane having at least two Si-Vi bonds per molecule, 0.002-0.005 parts by weight of an inhibitor, and the inhibitor is mixed in the component B.

11. The silicone composition according to claim 10, wherein the inhibitor is one or more selected from 2-methyl-3-butyn-2-ol, 2-phenyl-3-butyn-2-ol, 3,5-dimethyl-1-hexyn-3-ol, 1-hexyn-1-cyclohexanol, 3-ethyl-3-buten-1-yne, 1,3-divinyl tetramethyldisiloxane, 1,3,5,7-tetravinyltetramethylcyclotetarsiloxane, 1, 3-divinyl tetramethyldisiloxane, methyl tris(3-methyl-1-butyn-3-oxy)silane, tetramethylethylene diamine, benzotriazole, triphenylphosphine, and malaic acid derivatives.

12. The silicone composition according to claim 2, wherein the silicone composition further comprises, based on 100 parts by weight of the polymethylsiloxane having at least two Si-Vi bonds per molecule, 0.05-0.3 parts by weight of a tackifier, and the tackifier is mixed in the component B.

13. The silicone composition according to claim 12, wherein the tackifier is one or more selected from vinyltriethoxysilane, acryloylpropyltrimethoxysilane, alkylacryloylpropyltrimethoxysilane, allyltriethoxysilane, epoxypropxypropyltrimethoxysilane, allylglycidyl ether, an adduct of siloxane having a Si—H bond with allylglycidyl ether or methylacryloyloxy propyltrimethoxysilane, and a polycondensate prepared by cohydrolysis of trimethoxysilane with allyltrimethoxysilane.

14. The silicone composition according to claim 2, wherein based on 100 parts by weight of the polymethylsiloxane having at least two Si-Vi bonds per molecule, the component A contains 6-10 parts by weight of a mechanical functional filler, and the component B contains 6-10 parts by weight of the mechanical functional filler.

15. The silicone composition according to claim 14, wherein the mechanical functional filler is a hydrophobically treated filler particle, and the filler particle is one or more of activated calcium carbonate, fine silica powder, diatomaceous earth and titanium dioxide.

16. A method for preparing a reflective coating, comprising:
obtaining a base polymer component comprising 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds;
mixing a first portion of the base polymer component, a first portion of reflective particles, a first portion of mechanical functional filler, and a catalyst under a first stirring condition, to obtain a mixed component A;
mixing the remaining portion of the base polymer component, a second portion of reflective particles, a second portion of mechanical functional filler, a cross-linking agent, an inhibitor, and a tackifier under a second stirring condition, to obtain a mixed component B;
mixing the mixed component A and the mixed component B with stirring, to obtain a pre-material having a viscosity of 6000-10000 CP; and
applying the pre-material onto a substrate, followed by curing under a curing condition, to form a reflective coating,
wherein the cross-linking agent is a polyorganosiloxane having at least two Si—H bonds.

17. The method according to claim 16, wherein
the first stirring condition and the second stirring condition both comprise high-speed stirring at 2000-7000 rpm for 20-40 min; and
the curing condition comprises baking at 120-150° C. for 5-15 min.

18. The method according to claim 16, further comprising steps of grinding the mixed component A and the mixed component B separately before the step of mixing the mixed component A and the mixed component B with stirring,
wherein the grinding condition comprises grinding 2-3 times in a three-roller grinding mill with an inter-roller gap of 20-35 μm, to obtain a mixed component having a fineness of 20-35 μm.

19. A photovoltaic assembly, comprising a back panel and a reflective coating covering the back panel, wherein the reflective coating is formed by mixing and then curing a silicone composition comprising a base polymer component, a catalyst, a cross-linking agent and reflective particles, wherein the base polymer component comprises 100 parts by weight of a polymethylsiloxane having at least two Si-Vi bonds per molecule, 5-15 parts by weight of a hydrogenated epoxy resin or cycloaliphatic epoxy resin-modified polymethylvinylsiloxane terminated with a hydroxyl group, and 10-20 parts by weight of a siloxane resin having at least two Si-Vi bonds; and the cross-linking agent is a polyorganosiloxane having at least two Si—H bonds.

20. The photovoltaic assembly according to claim 19, wherein the silicone composition comprises a component A and a component B,
the component A comprises:
45-55 parts by weight of the polymethylsiloxane having at least two Si-Vi bonds per molecule;
2.5-7.5 parts by weight of the hydrogenated epoxy resin or cycloaliphatic epoxy resin-modified polymethylvinylsiloxane terminated with a hydroxyl group;
5-10 parts by weight of the siloxane resin having at least two Si-Vi bonds;
0.015-0.075 parts by weight of the catalyst; and
1.5-5 parts by weight of the reflective particles; and
the component B comprises:
45-55 parts by weight of the polymethylsiloxane having at least two Si-Vi bonds per molecule;
2.5-7.5 parts by weight of the hydrogenated epoxy resin or cycloaliphatic epoxy resin-modified polymethylvinylsiloxane terminated with a hydroxyl group;
5-10 parts by weight of the siloxane resin having at least two Si-Vi bonds;
0.75-10 parts by weight of the polyorganosiloxane cross-linking agent having at least two Si—H bonds; and
1.5-5 parts by weight of the reflective particles,
wherein the component A and the component B are formed separately.
